(19) United States
(12) Patent Application Publication
(10) Pub. No.: US 2006/0197440 A1
(43) Pub. Date: Sep. 7, 2006

(54) Organic EL display and method of manufacturing the same

(76) Inventors: Kenji Mitsui, Hakusan-shi (JP); Shuhei Yokoyama, Ishikawa-gun (JP); Tsuyoshi Uemura, Kanazawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/362,739

(22) Filed: Feb. 28, 2006

(30) Foreign Application Priority Data
Mar. 3, 2005 (JP) 2005-059216

(51) Int. Cl. H01J 1/62; H01J 63/04

(52) U.S. Cl. 313/504

(57) ABSTRACT

A method of manufacturing an organic EL display includes preparing a structure which includes an insulating substrate, a partition insulating layer disposed on a main surface of the insulating substrate and provided with an opening, and a first electrode disposed on the main surface of the insulating layer at a position corresponding to the opening, forming a first organic material layer by evaporating a first organic material onto the first electrode and heating the first organic material at a temperature higher than a melting point of the first organic material to melt the first organic material, forming an emitting layer on the first organic material layer by evaporation, and forming a second electrode on the emitting layer.

### CROSS-REFERENCE TO RELATED APPLICATIONS

This application is based upon and claims the benefit of priority from prior Japanese Patent Application No. 2005-059216, filed Mar. 3, 2005, the entire contents of which are incorporated herein by reference.

### BACKGROUND OF THE INVENTION

1. Field of the Invention

The present invention relates to an organic electroluminescent (EL) display and a method of manufacturing the same.

2. Description of the Related Art

An organic EL element includes an anode, a cathode, and an organic layer interposed therebetween. In the manufacture of organic EL elements using low-molecular-weight material for the organic layer, evaporation is normally utilized to deposit layers included in the organic layer.

In the manufacture of organic EL elements, foreign matter such as dust may adhere to a lower electrode before the deposition of the organic layer. It is difficult to completely remove such foreign matter by cleaning.

When an organic layer is deposited by evaporation with foreign matter attaching to the lower electrode, the organic layer may become thinner near the foreign matter or a pin hole may be created in the organic layer. This may concentrate electric fields in the vicinity of the foreign matter, thus degrading the organic EL element obtained or short-circuiting the anode and the cathode.

To solve this problem, Jpn. Pat. Appln. KOKAI Publication No. 2000-91067 describes the manufacture of an organic EL element by a method described below. First, a first layer included in an organic layer is formed by evaporation on a transparent electrode which serves as an anode. The first layer is then heated at its glass transition temperature or melting point. This allows the foreign matter adhering to the transparent electrode to be buried in the first layer. Subsequently, a second layer included in the organic layer is formed by evaporation. A metal electrode is further formed on the organic layer by evaporation.

This method may suppress the concentration of electric fields or a short circuit due to foreign matter. However, the inventors have found that it is difficult to achieve this effect by the above method.

### BRIEF SUMMARY OF THE INVENTION

According to a first aspect of the present invention, there is provided an organic EL display comprising an insulating substrate, a partition insulating layer which is disposed on a main surface of the insulating substrate and is provided with an opening, and an organic EL element which includes a first electrode disposed on the main surface of the insulating layer at a position corresponding to the opening, a second electrode facing the first electrode, and an organic layer interposed between the first and second electrodes and made of a low-molecular-weight organic compound, wherein the organic layer includes a first organic material layer which is disposed on the first electrode and whose thickness is smaller at a position corresponding to a center of the first electrode than at a position near a side wall of the opening, and an emitting layer which is interposed between the first organic material layer and the second electrode.

According to a second aspect of the present invention, there is provided an organic EL display comprising an insulating substrate, a partition insulating layer which is disposed on a main surface of the insulating substrate and is provided with an opening, and an organic EL element which includes a first electrode disposed on the main surface of the insulating layer at a position corresponding to the opening, a second electrode facing the first electrode, and an organic layer disposed between the first and second electrodes and made of a low-molecular-weight organic compound, wherein the organic layer includes a first organic material layer disposed on the first electrode and formed by evaporating a first organic material onto the first electrode and heating the first organic material on the first electrode at a temperature higher than a melting point of the first organic material, and an emitting layer interposed between the first organic material layer and the second electrode and formed by evaporation.

According to a third aspect of the present invention, there is provided a method of manufacturing an organic EL display, comprising preparing a structure which comprises an insulating substrate, a partition insulating layer disposed on a main surface of the insulating substrate and provided with an opening, and a first electrode disposed on the main surface of the insulating layer at a position corresponding to the opening, evaporating a first organic material onto the first electrode and heating the first organic material on the first electrode at a temperature higher than a melting point of the first organic material to form a first organic material layer, forming an emitting layer on the first organic material layer by evaporation, and forming a second electrode on the emitting layer.

According to a fourth aspect of the present invention, there is provided a method of manufacturing an organic EL display, comprising preparing a structure which comprises an insulating substrate, a partition insulating layer disposed on a main surface of the insulating substrate and provided with an opening, and a first electrode disposed on the main surface of the insulating layer at a position corresponding to the opening, evaporating a first organic material onto the first electrode and heating the first organic material on the first electrode at a temperature higher than a melting point of the first organic material to form a first organic material layer, depositing a second organic material onto the first organic material layer to form a second organic material layer which is thicker than the first organic layer and is equal in function to the first organic layer, forming an emitting layer on the second organic material layer, and forming a second electrode on the emitting layer.

### BRIEF DESCRIPTION OF THE SEVERAL VIEWS OF THE DRAWING

FIG. 1 is a sectional view schematically showing an organic EL display according to an embodiment of the present invention;

FIG. 2 is a sectional view schematically showing an example of a structure that can be adopted for an organic EL element of the organic EL display shown in FIG. 1;

FIG. 3 is a plan view schematically showing the organic EL display in FIG. 1;

FIGS. 4 to 9 are sectional views schematically showing a method of manufacturing an organic EL display according to the embodiment of the present invention; and

FIG. 10 is a graph showing an example of the influence of thickness of first and second organic material layers on a luminance unevenness.

### DETAILED DESCRIPTION OF THE INVENTION

An embodiment of the present invention will be described below in detail with reference to the drawings. In the drawings, components providing similar functions are denoted by the same reference numerals and duplicate descriptions will be omitted.

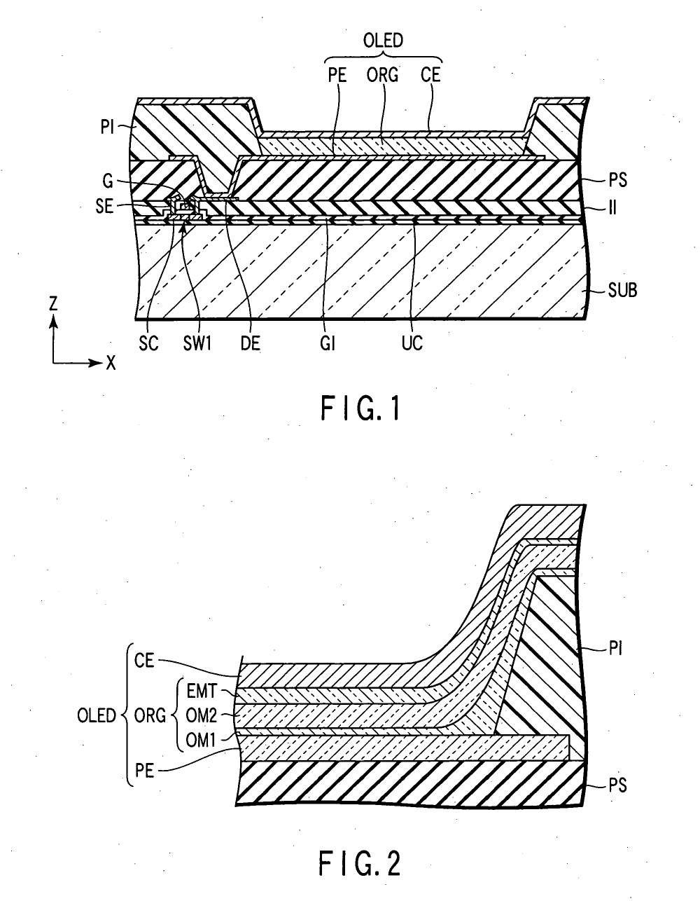

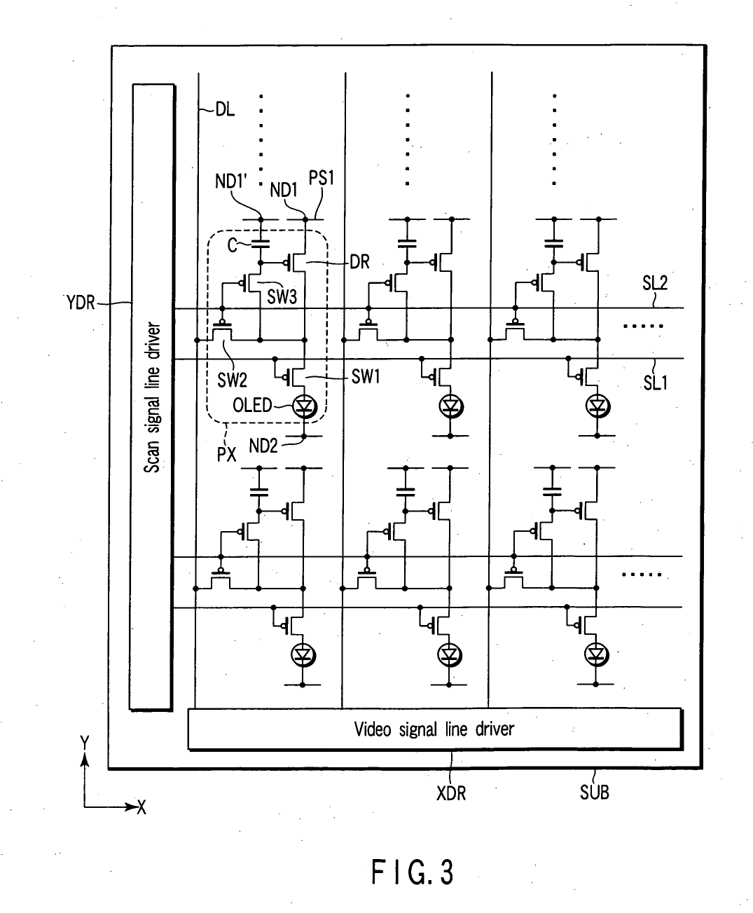

FIG. 1 is a sectional view schematically showing an organic EL display according to an embodiment of the present invention. FIG. 2 is a sectional view schematically showing an example of a structure that can be adopted for an organic EL element of the organic EL display shown in FIG. 1. FIG. 3 is a plan view schematically showing the organic EL display in FIG. 1. In FIG. 1, the organic EL display is drawn so that its display surface, that is, a front surface or a light emitting surface, faces the bottom of the drawing, while its back surface faces the top of the drawing.

The organic EL display is a bottom emission organic EL display adopting an active matrix driving method. The organic EL display includes an insulating substrate SUB, for example, a glass substrate.

As shown in FIG. 1, for example, an SiN_{X} layer and an SiO_{X} layer are sequentially stacked on the substrate SUB as an undercoat layer UC. Semiconductor layers SC in each of which source and drain are formed, a gate insulator GI, and gate electrodes G are sequentially stacked on the undercoat layer UC. For example, the semiconductor layers SC are polysilicon layers, the gate insulator GI is formed by using tetraethyl orthosilicate (TEOS), and the gate electrodes G are made of MoW. The semiconductor layers SC, gate insulator GI, and gate electrodes G constitute top gate-type TFTs. In this example, TFTs are p-channel TFTs used as a drive control element DR and switches SW1 to SW3 included in a pixel PX shown in FIG. 3.

Scan signal lines SL1 and SL2 are further arranged on the gate insulator GI. The scan signal lines SL1 and SL2 can be formed by the same step as that for the gate electrodes G. As shown in FIG. 3, the scan signal lines SL1 and SL2 extend along the rows of the pixels PX, i.e., in an X direction, and are alternately arranged in a Y direction along the columns of the pixels PX. The scan signal lines SL1 and SL2 are connected to a scan signal line driver YDR.

As shown in FIG. 1, the gate insulator GI, gate electrodes G, and signal lines SL1 and SL2 are covered with an interlayer insulating film II made of, for example, SiO_{X} and the like deposited by plasma CVD. Source electrodes SE and drain electrodes DE are arranged on the interlayer insulating film II and covered with a passivation film PS made of, for example, SiN_{X}. The source electrode SE and the drain electrode DE have a three-layer structure of, for example, Mo, Al, and Mo. The source electrodes SE and drain electrodes DE are electrically connected to sources and drains of TFTs via contact holes formed in the interlayer insulting film II.

Video signal lines DL are arranged on the interlayer insulating film II. Video signal lines DL can be formed by the same step as that for the source electrodes SE and drain electrodes DE. As shown in FIG. 3, the video signal lines DL extend in the Y direction and are arranged in the X direction. The video signal lines are connected to a video signal line driver XDR. Power supply lines PSL in FIG. 3 are typically laid on the layer on which the scan signal lines SL1 and SL2 are arranged or the layer on which the video signal lines DL are arranged.

As shown in FIG. 1, light-transmissive first electrodes PE are arranged on the passivation film PS such that the first electrodes PE are spaced apart from one another. The light-transmissive first electrodes PE serve as front electrodes. Each of the first electrodes PE is a pixel electrode connected to the drain electrode DE, which is connected to the switch SW1, via a through-hole formed in the passivation film PS.

The first electrode PE is an anode in this embodiment. A material for the first electrode PE is, for example, a transparent conductive oxide such as indium tin oxide (ITO).

A partition insulating layer PI is further placed on the passivation layer PS. In the partition insulating layer PI, through-holes are formed at positions corresponding to the first electrodes PE or slits are formed at positions corresponding to the columns or rows formed by the first electrodes PE. Here, by way of example, through-holes are formed in partition insulating layer PI at positions corresponding to the first electrodes PE.

The partition insulating layer PI is, for example, an organic insulating layer. The partition insulating layer PI can be formed using, for example, a photolithography technique.

Organic layers ORG each including an emitting layer are placed on the first electrodes PE. As shown in FIG. 2, the organic layer ORG includes a first organic material layer OM1, a second organic material layer OM2, and an emitting layer EMT.

The organic material layers OM1 and OM2 and emitting layer EMT are made of low-molecular-weight organic compound. These layers can be formed by, for example, evaporation such as vacuum evaporation. The term “low-molecular-weight organic compound” means an organic compound that can be used as a material for evaporation.

The first organic material layer OM1, second organic material layer OM2, and emitting layer EMT are arranged on the first electrode in this order. The first organic material layer OM1 and second organic material layer OM2 serve to mediate the injection of electric charges from the first electrode PE into the emitting layer. The first organic material layer OM1 and second organic material layer OM2 may be made of the same material or different materials.

In this embodiment, the first electrode PE is an anode. Consequently, a stack of the first organic material layer OM1 and second organic material layer OM2 serves as a hole injection layer or a hole transporting layer.

The emitting layer EMT is, for example, a thin film containing a luminescent organic compound that emits red, green, or blue light.

The organic layer ORG may further include layers other than the emitting layer EMT, hole injection layer, and hole transporting layer. For example, the organic layer ORG may further include a hole blocking layer, an electron transporting layer, and an electron injection layer.

The partition insulating layer PI and the organic layer ORG are covered with a second electrode CE serving as a back electrode. The second electrode CE is a common electrode shared by all the pixels PX. In this embodiment, the second electrode is a light-reflective cathode. The second electrode CE is electrically connected to an electrode wire (not shown) formed on the layer on which the video signal lines DL are formed, via a contact hole formed in the passivation film PS and partition insulating layer PI. Each organic EL element OLED is composed of the first electrode PE, organic layer ORG, and second electrode CE.

Each pixel PX includes the organic EL element OLED and a pixel circuit. In this embodiment, the pixel circuit includes a drive control element DR, an output control switch SW1, a selector switch SW2, a diode-connecting switch SW3, and a capacitor C as shown in FIG. 3. As described above, in this example, the drive control element DR and the switches SW1 to SW3 are p-channel TFTs.

The drive control element DR, the output control switch SW1, and the organic EL element OLED are connected in this order in series between a first power supply terminal ND1 and a second power supply terminal ND2. In this embodiment, the first power supply terminal ND1 is a high-potential power supply terminal. The second power supply terminal ND2 is a low-potential power supply terminal.

A gate of the output control switch SW1 is connected to the scan signal line SL1. The selector switch SW2 is connected between the video signal line DL and the drive control element DR. A gate of the selector switch SW2 is connected to the scan signal line SL2. The diode-connecting switch SW3 is connected between drain and gate of the drive control element DR. A gate of the diode-connecting switch SW3 is connected to the scan signal line SL2. The capacitor C is connected between the gate of the drive control element DR and a constant-potential terminal ND1′.

In this organic EL display, for example, the scan signal lines SL1 and SL2 are sequentially driven. During a write period in which a video signal is written to a certain pixel PX, the scan signal line driver YDR first outputs an off scan signal as a voltage signal to the scan signal line SL1 to which that pixel PX is connected, so as to open the switch SW1. The scan signal line driver YDR subsequently outputs an on scan signal as a voltage signal to the scan signal line SL2 to which the pixel PX is connected, so as to close the switches SW2 and SW3. The video signal line driver XDR then outputs a video signal as a current signal to the video signal line to which the pixel PX is connected, to set the gate-to-source voltage of the drive control element DR at a value corresponding to a magnitude of the video signal. Subsequently, the scan signal line driver YDR outputs an off scan signal as a voltage signal to the scan signal line SL2 to which that pixel PX is connected, so as to open the switches SW2 and SW3. The scan signal line driver YDR then outputs an on scan signal as a voltage signal to the scan signal line SL1 to which the pixel PX is connected, so as to close the switch SW1.

During an effective display period in which the switch SW1 is closed, a drive current having a magnitude corresponding to the gate-to-source voltage of the drive control element DR flows through the organic EL element OLED. The organic EL element OLED emits light at a luminance corresponding to the magnitude of the drive current.

The organic EL display is manufactured by, for example, the method described below.

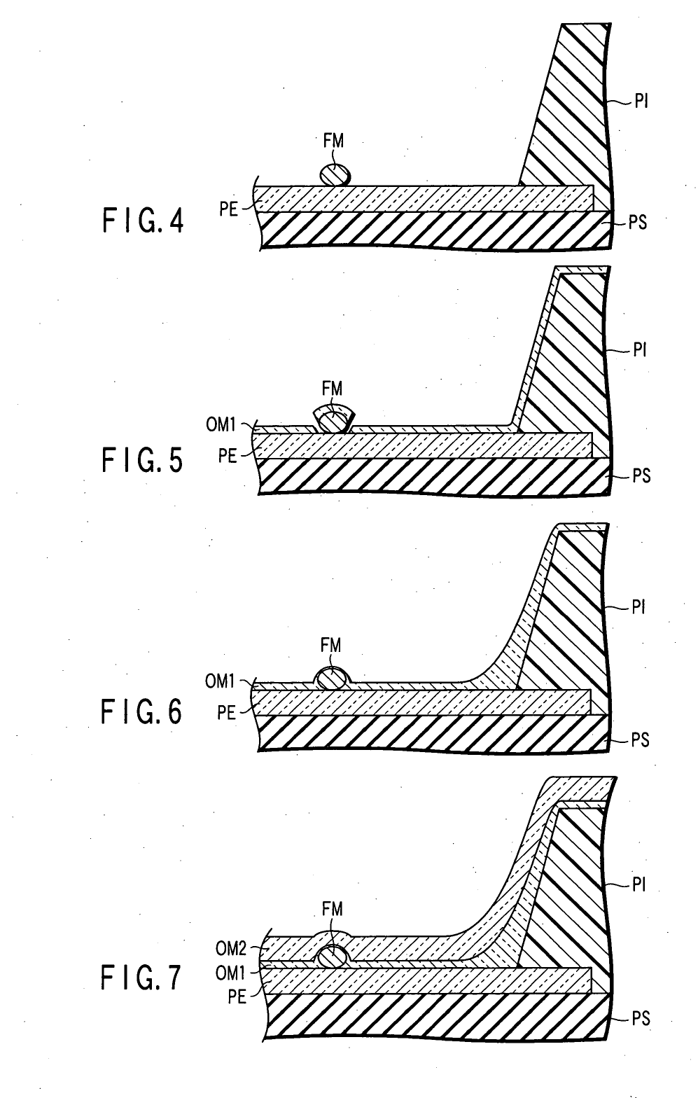

FIGS. 4 to 9 are sectional views schematically showing a method of manufacturing an organic EL display according to the embodiment of the present invention.

This method first executes a normal process of manufacturing an array substrate to obtain a structure shown in FIG. 4. The structure in FIG. 4 corresponds to the organic EL display in FIG. 2 from which the organic layer ORG and second electrode CE are omitted. In this structure, foreign matter FM may adhere to some of the first electrodes PE.

As shown in FIG. 5, a first organic material is then deposited on the first electrode PE by evaporation to obtain a first organic material layer OM1. For example, the first organic material layer OM1 is formed to have a thickness of about 20 nm or more at a position corresponding to a center of the first electrode PE after a melting process described later.

The first organic material is unlikely to deposit under the foreign matter FM and its vicinity. This may make the first organic material layer OM1 thinner near the foreign matter FM or may create a pin hole in the first organic material layer OM1 as shown in FIG. 5.

Subsequently, a melting process is executed to heat the first organic material layer OM1 at a temperature higher than its melting point. For example, the first organic material layer OM1 is heated so that the difference between the heating temperature and melting point of the first organic material is between 10° and 20° C.

The melting process sufficiently fluidizes the first organic material. This causes the foreign matter FM to be buried in the first organic material layer OM1 as shown in FIG. 6. The melting process also makes the first organic material layer OM1 thinner in its part over the center of the first electrode PE than in its part located near the side wall of the opening formed in the partition insulating layer PI as shown in FIG. 6. Normally, the ratio D₁/D₀ of a thickness D₁ to a thickness D₀ falls within a range from about 0.5 to about 0.8, where the thickness D₁ is the thickness of part of the first organic material layer OM1 located over the center of the first electrode PE, and the thickness D₀ is the thickness of part of the first organic material layer OM1 located at the lower end of the side wall of the through-hole formed in the partition insulating layer PI.

A second organic material is deposited on the first organic material layer OM1 by evaporation. The second organic material layer OM2 shown in FIG. 7 is thus obtained.

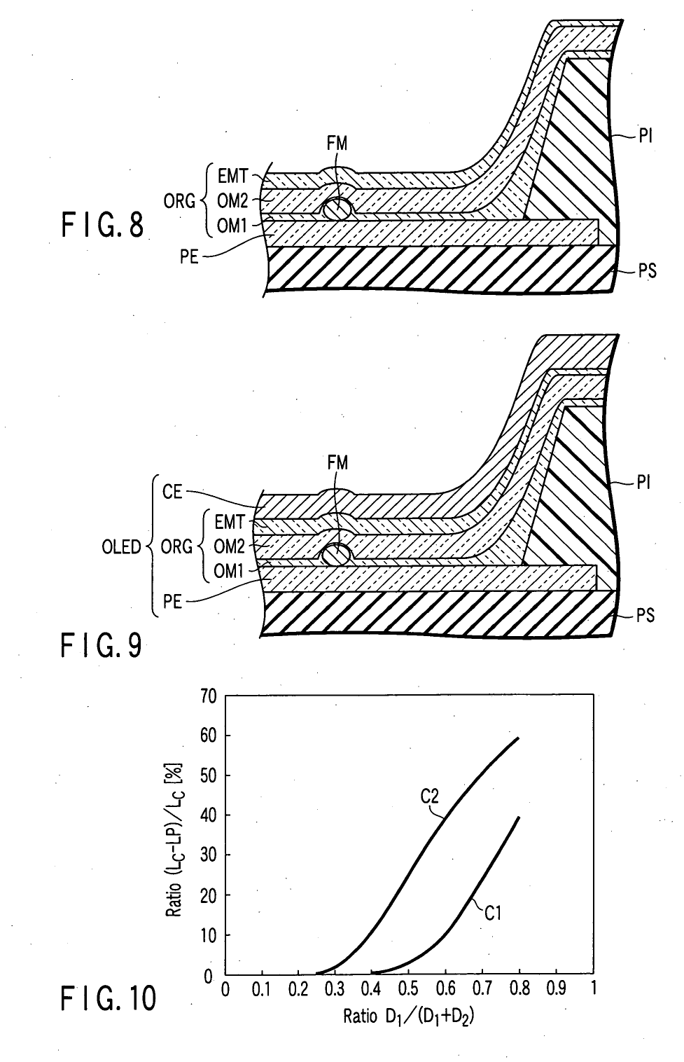

Subsequently, as shown in FIGS. 8 and 9, an emitting layer EMT and a second electrode OM2 are sequentially formed on the second organic material layer OM2 by evaporation.

This method sets the heating temperature for the melting process higher than the melting point of the first organic material. The first organic material can thus be sufficiently fluidized. This makes it possible to prevent a pin hole from being created in the first organic material layer OM1 near the foreign matter FM. It is also possible to prevent the part of the first organic material layer OM1 located near the foreign matter FM from being markedly thinner than the surrounding parts. That is, this method can prevent the degradation due to the concentration of electric fields and the short circuit between the first electrode PE and second electrode CE in the vicinity of the foreign matter FM.

If the first organic material layer OM1 is heated to a temperature within a range from its glass transition temperature to its melting point instead of carrying out the melting process, it would be possible to cause a phase change of the first organic material from amorphous phase to crystal phase. However, this fails to sufficiently fluidize the first organic material. In this case, it is difficult to achieve the above effect.

With the method described above, the melting process makes the first organic material layer OM1 thinner in its part over the center of the first electrode PE than in its part located near the side wall of the opening formed in the partition insulating layer PI. The electric resistance of the first organic material layer OM1 is in proportion to its thickness. Thus, if a current is made to flow between the first electrode PE and the second electrode CE in a structure that the second organic material layer OM2 is not placed between the first organic material layer OM1 and the emitting layer EMT, the current density would be increased at the center of the emitting layer than that its peripheries. The unevenness in current density may be viewed as a luminance unevenness in the pixel PX.

By placing the second organic material layer OM2 between the first organic material layer OM1 and the emitting layer EMT, it is possible to reduce the influence of thickness unevenness of the first organic material layer OM1 on the uniformity of the current density. This enables the suppression of the luminance unevenness in the pixel PX.

The second organic material layer OM2 may be thicker than the first organic material layer OM1. There is a possibility that the thickness of the first organic material layer at its center portion differs from the thickness of the first organic material layer at its peripheral portion. When the first organic material layer OM1 is relatively thick, the difference in thickness between the center portion and the peripheral portion is large. Therefore, in the case that the first organic material layer OM1 is thicker than the second organic material layer OM2, a multilayer including the first organic layer OM1 and the second organic layer OM2 may produce a large difference in thickness between center and peripheral portions thereof. When the first organic material layer OM1 is relatively thin, the difference in thickness between the center portion and the peripheral portion is small. Therefore, in the case that the first organic material layer OM1 is thinner than the second organic material layer OM2, it would be possible to prevent a large difference in thickness from being produced between the center and peripheral portions of the multilayer including the first organic layer OM1 and the second organic layer OM2.

The effect of suppressing the luminance unevenness in the pixel PX achieved by the second organic material layer OM2 depends on the thickness of the first organic material layer OM1 and second organic material layer OM2. This will be described with reference to FIG. 10.

FIG. 10 is a graph showing an example of the influence of thickness of first and second organic material layers on a luminance unevenness. In the figure, the abscissa indicates the ratio D₁/(D₁+D₂) of the thickness D₁ of the first organic material layer to the sum D₁+D₂ of thicknesses D₁ and D₂ of the first and second organic material layers, at a position corresponding to the center of the first electrode PE. The ordinate indicates, in percentage, the ratio (L_{c}−Lₚ)/L_{c} of the difference between the luminance L_{c} of the organic EL element OLED at a position corresponding to the center of the first electrode PE and the luminance Lₚ of the organic EL element OLED at a position near the side wall of the through-hole formed in the partition insulating layer PI, to the luminance L_{c}.

The data in FIG. 10 has been obtained under the following conditions. The material for the first organic material layer OM1 and second organic material layer OM2 was N,N′-bis(4-diphenylamino-4′-biphenyl)-N,N′-diphenyl{1,1′-biphenyl}-4,4′-diamine, which has a melting point of about 150° C. The sum D₁+D₂ was set at a fixed value, and the heating temperature in the melting process was set at 160° and 170° C. In FIG. 10, a curve C1 shows data obtained when the heating temperature was set at 160° C. A curve C2 shows data obtained when the heating temperature was set at 170° C.

As shown in FIG. 10, the ratio (L_{c}−Lₚ)/L_{c} is sufficiently small if the ratio D₁/(D₁+D₂) is small. That is, the luminance unevenness in the pixel PX is sufficiently suppressed. For example, the curve C1 shows that the ratio (L_{c}−Lₚ)/L_{c} is about 10% or less when the ratio D₁/(D₁+D₂) is about 0.6 or less. The curve C2 shows that the ratio (L_{c}−Lₚ)/L_{c} is about 10% or less when the ratio D₁/(D₁+D₂) is about 0.4 or less. The luminance unevenness in the pixel PX can be sufficiently suppressed by appropriately setting the ratio D₁/(D₁+D₂).

The bottom emission organic EL display has been described. However, the above technique is also applicable to a top emission organic EL display.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An organic EL display comprising:
an insulating substrate;
a partition insulating layer which is disposed on a main surface of the insulating substrate and is provided with an opening; and
an organic EL element which includes a first electrode disposed on the main surface of the insulating layer at a position corresponding to the opening, a second electrode facing the first electrode, and an organic layer interposed between the first and second electrodes and made of a low-molecular-weight organic compound, wherein the organic layer includes a first organic material layer which is disposed on the first electrode and whose thickness is smaller at a position corresponding to a center of the first electrode than at a position near a side wall of the opening, and an emitting layer which is interposed between the first organic material layer and the second electrode.

2. The display according to claim 1, wherein the organic layer further includes a second organic material layer interposed between the first organic material layer and the emitting layer.

3. The display according to claim 2, wherein the first and second organic material layers are equal in material.

4. The display according to claim 2, wherein a ratio D₁/(D₁+D₂) is equal to 0.6 or less, D₁ and D₂ being thicknesses of the first and second organic material layers at a position corresponding to a center of the first electrode, respectively.

5. An organic EL display comprising:
an insulating substrate;
a partition insulating layer which is disposed on a main surface of the insulating substrate and is provided with an opening; and
an organic EL element which includes a first electrode disposed on the main surface of the insulating layer at a position corresponding to the opening, a second electrode facing the first electrode, and an organic layer disposed between the first and second electrodes and made of a low-molecular-weight organic compound, wherein the organic layer includes a first organic material layer disposed on the first electrode and formed by evaporating a first organic material onto the first electrode and heating the first organic material on the first electrode at a temperature higher than a melting point of the first organic material, and an emitting layer interposed between the first organic material layer and the second electrode and formed by evaporation.

6. The display according to claim 5, wherein the organic layer further includes a second organic material layer interposed between the first organic material layer and the emitting layer.

7. The display according to claim 6, wherein the first and second organic material layers are equal in material.

8. The display according to claim 6, wherein a ratio D₁/(D₁+D₂) is equal to 0.6 or less, D₁ and D₂ being thicknesses of the first and second organic material layers at a position corresponding to a center of the first electrode, respectively.

9. A method of manufacturing an organic EL display, comprising:
preparing a structure which comprises an insulating substrate, a partition insulating layer disposed on a main surface of the insulating substrate and provided with an opening, and a first electrode disposed on the main surface of the insulating layer at a position corresponding to the opening;
evaporating a first organic material onto the first electrode and heating the first organic material on the first electrode at a temperature higher than a melting point of the first organic material to form a first organic material layer;
forming an emitting layer on the first organic material layer by evaporation; and
forming a second electrode on the emitting layer.

10. The method according to claim 9, further comprising evaporating a second organic material onto the first organic material layer to form a second organic material layer after forming the first organic material layer and before forming the emitting layer.

11. The method according to claim 10, wherein the first organic material is the same as the second organic material.

12. The method according to claim 9, wherein a difference between the temperature at which the first organic material is heated and the melting point of the first organic material layer falls within a range from 10° C. to 20° C.

13. A method of manufacturing an organic EL display, comprising:
preparing a structure which comprises an insulating substrate, a partition insulating layer disposed on a main surface of the insulating substrate and provided with an opening, and a first electrode disposed on the main surface of the insulating layer at a position corresponding to the opening;
evaporating a first organic material onto the first electrode and heating the first organic material on the first electrode at a temperature higher than a melting point of the first organic material to form a first organic material layer;
depositing a second organic material onto the first organic material layer to form a second organic material layer which is thicker than the first organic layer and is equal in function to the first organic layer;
forming an emitting layer on the second organic material layer; and
forming a second electrode on the emitting layer.

14. The method according to claim 13, wherein the first organic material is the same as the second organic material.

15. The method according to claim 13, wherein a difference between the temperature at which the first organic material is heated and the melting point of the first organic material layer falls within a range from 10° C. to 20° C.
